(19) United States
(12) Patent Application Publication
(10) Pub. No.: US 2025/0151378 A1
(43) Pub. Date: May 8, 2025

(54) SEMICONDUCTOR DEVICE

(71) Applicant: SUMITOMO ELECTRIC INDUSTRIES, LTD., Osaka (JP)

(72) Inventors: Hayato SHIMIZU, Osaka (JP); Sadanori Arae, Osaka (JP)

(73) Assignee: SUMITOMO ELECTRIC INDUSTRIES, LTD., Osaka (JP)

(21) Appl. No.: 18/931,423

(22) Filed: Oct. 30, 2024

(30) Foreign Application Priority Data
Nov. 6, 2023 (JP) 2023-189226

(51) Int. Cl. H01L 27/06; H01L 23/48; H01L 29/778

(52) U.S. Cl. CPC H10D 84/811; H01L 23/481; H10D 1/714; H10D 30/47

(57) ABSTRACT

A semiconductor device includes a transistor provided on a main surface of a substrate having the main surface, and including a first electrode including an ohmic electrode, a MIM capacitor formed above the transistor and including a second electrode, a first electrically insulating layer provided on the second electrode, and a third electrode provided on the first electrically insulating layer, a second electrically insulating layer provided between the first electrode and the second electrode, and a plurality of vias penetrating the second electrically insulating layer and electrically connecting the first electrode and the second electrode to each other.

### CROSS-REFERENCE TO RELATED APPLICATIONS

This application claims priority based on Japanese Patent Application No. 2023-189226 filed on Nov. 6, 2023, and the entire contents of the Japanese patent application are incorporated herein by reference.

### TECHNICAL FIELD

The present disclosure relates to a semiconductor device.

### BACKGROUND ART

Patent literature 1 discloses a technique related to an optical semiconductor element having an MIM capacitor. The technique includes the MIM capacitor formed on a semiconductor substrate and composed of a lower electrode, a dielectric film, and an upper electrode. A first interlayer insulating film provided with a first via hole and a second interlayer insulating film provided with a second via hole are formed on the upper electrode of the MIM capacitor. A wiring layer connected to the upper electrode through the first via hole and the second via hole is formed on the second interlayer insulating film, and a vertical distance between the lower electrode of the MIM capacitor and the wiring layer is increased. Patent literature 1: Japanese Unexamined Patent Application Publication No. 2004-193563
Patent literature 2: Japanese Unexamined Patent Application Publication No. 2011-165931
Patent literature 3: Japanese Unexamined Patent Application Publication No. 2004-022773
Patent literature 4: Japanese Unexamined Patent Application Publication No. 2017-059621

### SUMMARY OF THE INVENTION

A semiconductor device according to an embodiment of the present disclosure includes a transistor, a MIM capacitor, a second electrically insulating layer and a plurality of vias. The transistor is provided on a main surface of a substrate having the main surface, and includes a first electrode including an ohmic electrode. The MIM capacitor is formed above the transistor and includes a second electrode, a first electrically insulating layer provided on the second electrode, and a third electrode provided on the first electrically insulating layer. The second electrically insulating layer is provided between the first electrode and the second electrode. The plurality of vias penetrate the second electrically insulating layer and electrically connect the first electrode and the second electrode to each other.

### BRIEF DESCRIPTION OF THE DRAWINGS

FIG. 1 is a plan view showing a semiconductor device according to a first embodiment of the present disclosure.

FIG. 2 is a circuit diagram of a semiconductor device according to a first embodiment.

FIG. 3 is a cross-sectional view taken along line III-III shown in FIG. 1.

FIG. 4 is a plan view showing a transistor.

FIG. 5 is a cross-sectional view taken along line V-V shown in FIG. 1.

FIG. 6 is a cross-sectional view taken along line VI-VI shown in FIG. 1.

FIG. 7 is a plan view of a semiconductor device according to a second embodiment.

FIG. 8 is a circuit diagram of a semiconductor device according to a second embodiment.

FIG. 9 is a cross-sectional view take along line IX-IX shown in FIG. 7.

FIG. 10 is a plan view showing an amplifier of a semiconductor device according to a third embodiment.

FIG. 11 is a cross-sectional view take along line XI-XI shown in FIG. 10.

FIG. 12 is a plan view showing a semiconductor device that is a comparative example.

FIG. 13 is a circuit diagram of a semiconductor device that is a comparative example.

FIG. 14 is a Smith chart showing impedance characteristics in a semiconductor device according to a first embodiment and a semiconductor device that is a comparative example.

FIG. 15 is a circuit diagram of an amplifier circuit that is a verification example.

FIG. 16 is a diagram showing characteristics of an amplifier circuit that is a verification example.

FIG. 17 is a circuit diagram of a Doherty amplifier circuit that is a verification example.

FIG. 18 is a diagram showing characteristics of a Doherty amplifier circuit that is a verification example.

### DETAILED DESCRIPTION

Conventionally, in an amplifier, a transistor, such as a High Electron Mobility Transistor (HEMT), and a Metal-Insulator-Metal (MIM) capacitor are arranged on the substrate in a direction along the substrate surface and connected to each other via routing wiring. When the routing wiring becomes longer, and thus an inductance component of a circuit becomes larger. Due to the influence of the inductance component, the adjustment of impedance becomes complicated, and a wiring length tends to be long. As the wiring length becomes longer, the loss increases and the efficiency of the amplifier is likely to decrease.

An object of the present disclosure is to provide a semiconductor device in which the efficiency of an amplifier is less likely to decrease.

### Description of Embodiments of Present Disclosure

First, details of the embodiments of the present disclosure will be illustrated and described.
[1] A semiconductor device according to an embodiment of the present disclosure includes a transistor, a MIM capacitor, a second electrically insulating layer and a plurality of vias. The transistor is provided on a main surface of a substrate having the main surface, and includes a first electrode including an ohmic electrode. The MIM capacitor is formed above the transistor and includes a second electrode, a first electrically insulating layer provided on the second electrode, and a third electrode provided on the first electrically insulating layer. The second electrically insulating layer is provided between the first electrode and the second electrode. The plurality of vias penetrate the second electrically insulating layer and electrically connect the first electrode and the second electrode to each other.

In the semiconductor device of the above [1], the MIM capacitor is formed above the transistor, and the transistor and the MIM capacitor are electrically connected to each other by the plurality of vias. Thus, the distance between the transistor and the MIM capacitor is shorter than the distance between the transistor and the MIM capacitor in the case where the MIM capacitor and the transistor are arranged in the direction along the main surface and the transistor and the MIM capacitor are connected by routing wiring. Thus, the magnitude of inductance component between the transistor and the MIM capacitor in the configuration of the semiconductor device of [1] is smaller than that in the case where the transistor and the MIM capacitor are connected by the routing wiring. Thus, since the loss is reduced, a semiconductor device in which the efficiency of the amplifier is less likely to decrease can be obtained.

In addition, the surface of the ohmic electrode is roughened by annealing during the manufacturing process, and thus the surface of the first electrode is also roughened. However, in the film formation process of the second electrically insulating layer provided between the first electrode and the second electrode, the surface of the second electrically insulating layer is less likely to inherit the condition of the surface of the first electrode. That is, even when the surface of the first electrode has irregularities, the surface of the second electrically insulating layer can be made nearly flat. Thus, the surface of the second electrode formed on the second electrically insulating layer can also be made flat. Thus, it is possible to reduce electric field from locally increasing, and the reliability of the MIM capacitor can be enhanced.

Further, since the plurality of vias are interposed between the first electrode and the second electrode, the sum of the cross-sectional areas of all the plurality of vias in the plane along the main surface is increased as compared with the case where a single via is provided, and thus current flows more easily between the first electrode and the second electrode. Thus, the loss is reduced, thereby reducing the efficiency of the amplifier from being reduced.

[2] In the semiconductor device of the above [1], the MIM capacitor may be provided to avoid an area above a gate electrode of the transistor. Thus, parasitic capacitance generated between the MIM capacitor and the gate electrode can be reduced. Thus, the parasitic capacitance is reduced in addition to the reduction of the inductance component, thereby further reducing the efficiency of the amplifier from being reduced.

[3] In the semiconductor device of the above [1], the MIM capacitor may fit in an area above the first electrode when viewed in a direction perpendicular to the main surface. Thus, a portion where the MIM capacitor is formed is limited to an area above the first electrode, thereby reducing parasitic capacitance generated between the MIM capacitor and a region other than the first electrode. Thus, the parasitic capacitance is reduced in addition to the reduction of the inductance component, thereby further reducing the efficiency of the amplifier from being reduced.

[4] In the semiconductor device of the above [1], the MIM capacitor may include a first portion fitting in an area above the first electrode when viewed in a direction perpendicular to the main surface, and a second portion provided outside the transistor when viewed in the direction perpendicular to the main surface, the second portion being continuous with the first portion. Thus, parasitic capacitance generated between the MIM capacitor and a region other than the first electrode can be reduced in both the first portion and the second portion. In addition, since the MIM capacitor has the second portion in addition to the first portion, the area of the electrode of the MIM capacitor is increased, and thus the capacitance of the MIM capacitor can be increased. In the semiconductor device of [4], the MIM capacitor is provided for the purpose of DC cutting, for example. As the capacitance of the MIM capacitor increases, the cut-off frequency decreases. Thus, it is possible to perform DC cutting at a lower frequency, and it is possible to perform DC cutting in a wide frequency bandwidth.

[5] In the semiconductor device of the above [1] to [4], the transistor may be a HEMT including a III-V group semiconductor. Generally, HEMT can withstand a high voltage and can handle a large current, and thus, can amplify a high output. Thus, the efficiency of the amplifier can be further improved by using the HEMT as the transistor.

[6] In the semiconductor device of the above [1] to [5], a dielectric constant of the first electrically insulating layer may be larger than a dielectric constant of the second electrically insulating layer. This makes it possible to further increase the capacitance of the MIM capacitor. In the semiconductor device of [6], the MIM capacitor is provided for the purpose of DC cutting, for example. As the capacitance of the MIM capacitor increases, the cut-off frequency decreases. Thus, it is possible to perform DC cutting at a lower frequency, and it is possible to perform DC cutting in a wide frequency bandwidth.

[7] In the semiconductor device of the above [1] to [6], a thickness of the first electrically insulating layer in a direction perpendicular to the main surface may be smaller than a thickness of the second electrically insulating layer in the direction perpendicular to the main surface. By reducing the thickness of the first electrically insulating layer, the capacitance of the MIM capacitor can be increased. In the semiconductor device of [7], the MIM capacitor is provided for the purpose of DC cutting, for example. As the capacitance of the MIM capacitor increases, the cut-off frequency decreases. Thus, it is possible to perform DC cutting at a lower frequency, and it is possible to perform DC cutting in a wide frequency bandwidth.

[8] In the semiconductor device of the above [1] to [7], a thickness of the second electrode in a direction perpendicular to the main surface may be smaller than a thickness of the first electrode in the direction perpendicular to the main surface. By reducing the thickness of the second electrode, deposition time of the electrically insulating layer that embeds the second electrode can be shortened.

[9] In the semiconductor device of the above [1] to [8], lengths of the plurality of vias in a direction perpendicular to the main surface may be 0.1 μm to 10 μm. When the transistor and the MIM capacitor are connected by routing wiring, the distance between the transistor and the MIM capacitor tends to be long distance of, for example, several hundred micrometer or more. In contrast, according to the semiconductor device of the above [1], for example, as in the above [9], the distance of the wiring (via) between the transistor and the MIM capacitor can be shortened. Thus, a semiconductor device in which the efficiency of the amplifier is less likely to be reduced can be realize.

### Details of Embodiments of Present Disclosure

Specific examples of the semiconductor device of the present disclosure will be described below with reference to the drawings. It is noted that the present invention is not limited to the following examples, but the present invention is illustrated in the claims and is intended to include all modified examples within the meaning and the scope of the claims. In the description of the drawings, the same elements are designated by the same reference numerals, and duplicated descriptions will be omitted as appropriate.

### First Embodiment

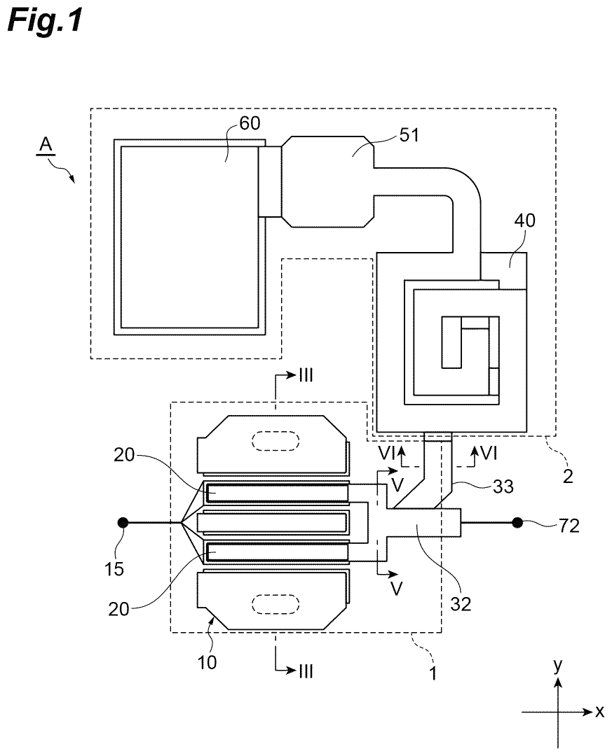

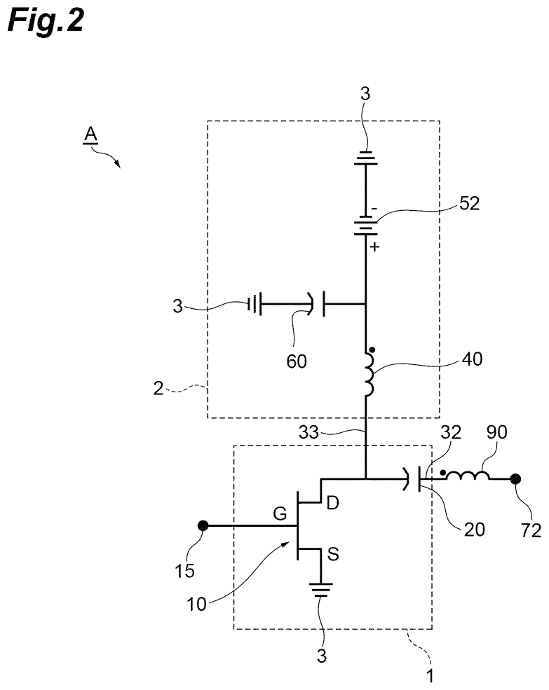

FIG. 1 is a plan view showing a semiconductor device A according to a first embodiment of the present disclosure. FIG. 2 is a circuit diagram of semiconductor device A according to the first embodiment of the present disclosure. Semiconductor device A includes an amplifier 1, a bias circuit 2, an input terminal 15, and an output terminal 72. Input terminal 15 is provided on the input side of amplifier 1, and output terminal 72 is provided on the output side of amplifier 1.

Amplifier 1 has a transistor 10 and a plurality of (two in the illustrative example) MIM capacitors 20. Bias circuit 2 has an inductor 40, a MIM capacitor 60, an external power supply 52 (see FIG. 2), and a pad 51 (see FIG. 1) for connection to external power supply 52. In transistor 10, a gate is connected to input terminal 15. A source is connected to a ground potential line 3 (see FIG. 2). A drain is connected to a first electrode of each MIM capacitor 20 and is connected to one end of inductor 40 of bias circuit 2 via a wiring 33. A second electrode of each MIM capacitor 20 is connected to output terminal 72 via a wiring 32. The other end of inductor 40 is connected to the first electrode of MIM capacitor 60 and is also connected to a positive electrode of external power supply 52 via pad 51. Inductor 40 is, for example, a spiral inductor. The second electrode of MIM capacitor 60 and a negative electrode of external power supply 52 are connected to ground potential lines 3.

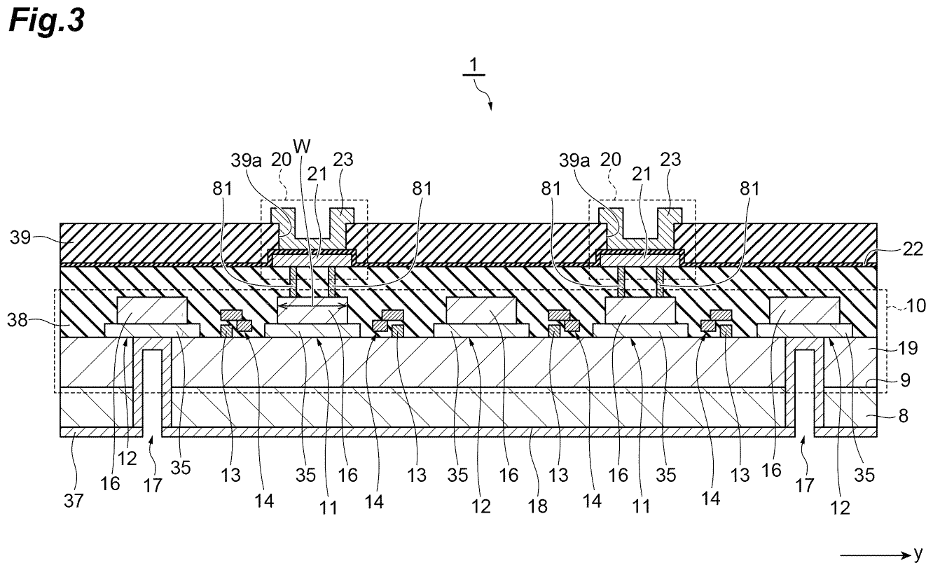

FIG. 3 is a cross-sectional view taken along line III-III shown in FIG. 1. Amplifier 1 includes a substrate 8 having a main surface 9 and a back surface 18. Transistor 10 is provided on main surface 9 of substrate 8. Transistor 10 includes a plurality of (two in the illustrative example) drain electrodes 11, a plurality of (three in the illustrative example) source electrodes 12, a plurality of (four in the illustrative example) gate electrodes 13, and a semiconductor layer 19. The plurality of drain electrodes 11 and the plurality of source electrodes 12 are alternately arranged in a predetermined direction y, and a gap is provided between each drain electrode 11 and each source electrode 12. Each gate electrode 13 is arranged in the gap between drain electrode 11 and source electrode 12. Each of drain electrode 11 (first electrode) and source electrode 12 includes an ohmic electrode 35 and a wiring 16. Transistor 10 is, for example, a HEMT including a III-V group semiconductor in semiconductor layer 19. Semiconductor layer 19 is composed of a semiconductor such as GaAs, InGaAs, AlGaAs, or GaN.

Ohmic electrode 35 is provided on semiconductor layer 19. Ohmic electrode 35 has a film shape. The material of ohmic electrode 35 is, for example, titanium (Ti) or nickel (Ni). Wiring 16 is provided on ohmic electrode 35 and is in contact with ohmic electrode 35. The material of wiring 16 is, for example, gold (Au). A thickness of wiring 16 in the direction perpendicular to main surface 9 is, for example, 0.1 μm to 10 μm. A width W of wiring 16 along the y direction, which is the direction in which drain electrode 11, source electrode 12, and gate electrode 13 are arranged, is, for example, 1 μm to 1000 μm. The area of wiring 16 viewed in the direction perpendicular to main surface 9 is, for example, 1 μm² to 1000000 μm².

Amplifier 1 further includes a field plate 14, a backside electrode 37, and a via 17. Field plate 14 is provided above gate electrode 13 and between gate electrode 13 and drain electrode 11. Field plate 14 is set to a reference potential and controls the distribution of electric field. Backside electrode 37 is provided over the entire surface of back surface 18 of substrate 8. Backside electrode 37 is connected to ground potential line 3 shown in FIG. 2, and is thereby set to a reference potential. Via 17 is provided to penetrate substrate 8 and semiconductor layer 19 from back surface 18 of substrate 8 to source electrode 12. Via 17 is in contact with backside electrode 37 and ohmic electrode 35 of source electrode 12. That is, source electrode 12 is connected to ground potential line 3 via backside electrode 37 and via 17.

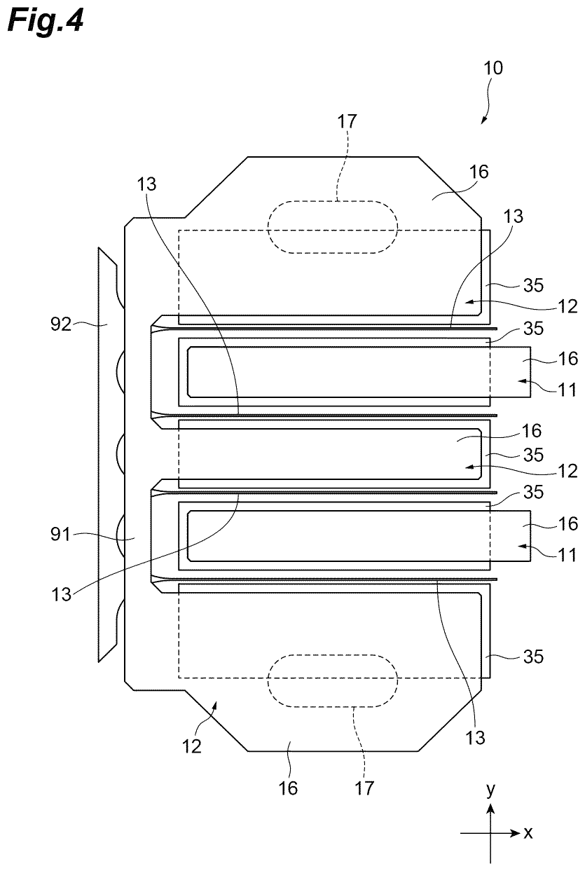

FIG. 4 is a plan view showing transistor 10. Each of drain electrodes 11 and each of source electrodes 12 have rectangular shapes which are long along the x direction intersecting with the y direction and extending along main surface 9. One ends of wirings 16 of the plurality of source electrodes 12 in the x direction are connected to each other by a wiring 91 which is provided in a region outside ohmic electrode 35 and is long in the y direction. One ends of the plurality of gate electrodes 13 in the x direction are connected to each other by a wiring 92 which is long in the y direction. Input terminal 15 (see FIGS. 1 and 2) is connected to gate electrodes 13 via wiring 92.

Refer again to FIG. 3. Amplifier 1 further includes a plurality of vias 81, an electrically insulating layer 38, and an electrically insulating layer 39. Electrically insulating layer 38 (second electrically insulating layer) is provided between wiring 16 and a lower electrode 21 (described later) of MIM capacitor 20. That is, electrically insulating layer 38 is provided on drain electrode 11 and source electrode 12. Further, electrically insulating layer 38 is also provided on gate electrode 13, and is provided over entire semiconductor layer 19. The material of electrically insulating layer 38 is, for example, an insulating material containing Si such as SiO₂, SiN, or SiON, or a resinous material such as polyimide. Electrically insulating layer 39 is provided above electrically insulating layer 38. Electrically insulating layer 39 is provided over entire electrically insulating layer 38. The material of electrically insulating layer 39 is, for example, an insulating material containing Si such as SiO₂, SiN, or SiON, or a resinous material such as polyimide. The plurality of vias 81 penetrate electrically insulating layer 38 and electrically connect wiring 16 and lower electrode 21. That is, the plurality of vias 81 are interposed between wiring 16 and lower electrode 21. Each of the plurality of vias 81 fits in an area above each drain electrode 11 when viewed in the direction perpendicular to main surface 9. A length of via 81 in the direction perpendicular to main surface 9 is, for example, 0.1 μm to 10 μm. The diameter of each via 81 is, for example, 0.5 μm to 10 μm. The number of vias 81 is, for example, 1 to 1000000. The material of the member constituting via 81 is, for example, at least one of Au, Ti, Al, Ta, W, Cu, Pt, Mo, Ni, Pd, Cr, Co, or Ru.

Each of MIM capacitors 20 includes lower electrode 21 (second electrode), a dielectric material layer 22 (first electrically insulating layer), and an upper electrode 23 (third electrode). Each of MIM capacitors 20 is formed above each drain electrode 11. MIM capacitor 20 has a rectangular shape elongated in the x direction when viewed in the direction perpendicular to main surface 9 (see FIG. 1). Each of MIM capacitors 20 of the present embodiment is provided in amplifier 1 for purpose of DC cutting.

Each MIM capacitor 20 is provided to avoid an area above gate electrode 13 of transistor 10. In one example, as in the present embodiment, each MIM capacitor 20 fits in an area above drain electrode 11 of transistor 10 when viewed in the direction perpendicular to main surface 9. Lower electrode 21 is provided between electrically insulating layer 38 and electrically insulating layer 39. The material of lower electrode 21 is, for example, at least one of Au, Ti, Al, Ta, W, Cu, Pt, Mo, Ni, Pd, or Cr. In the y direction, a width of lower electrode 21 is equal to or smaller than a width of drain electrode 11. The width of lower electrode 21 along the y direction is, for example, 1 μm to 1000 μm. The area of lower electrode 21 viewed in the direction perpendicular to main surface 9 is, for example, 1 μm² to 1000000 μm². A thickness of lower electrode 21 in the direction perpendicular to main surface 9 is smaller than a thickness of wiring 16 in the same direction. The thickness of lower electrode 21 in the same direction is, for example, 0.1 μm to 10 μm.

Dielectric material layer 22 is provided between electrically insulating layer 38 and electrically insulating layer 39, and is formed over electrically insulating layer 38 and lower electrode 21. Dielectric material layer 22 is in contact with the entire region of the surface of lower electrode 21 facing upper electrode 23. In other words, lower electrode 21 is in contact with electrically insulating layer 38 on the surfaces connected to the plurality of vias 81, and is in contact with dielectric material layer 22 on all the other surfaces along the x direction. The material of dielectric material layer 22 is, for example, an insulating material containing Si such as SiO₂, SiN, or SiON, a resinous material such as polyimide, or a metal-oxide such as hafnium oxide (HfO₂) or aluminum oxide (Al₂O₃).

Upper electrode 23 is provided above lower electrode 21 and on dielectric material layer 22. Upper electrode 23 has a portion provided on electrically insulating layer 39 and a portion provided along the surface of an opening 39a formed in electrically insulating layer 39. In addition, upper electrode 23 further includes a portion in contact with dielectric material layer 22 at the bottom of opening 39a. Opening 39a fits in an area above lower electrode 21 when viewed in the direction perpendicular to main surface 9. The material of upper electrode 23 is, for example, at least one of Au, Ti, Al, Ta, W, Cu, Pt, Mo, Ni, Pd, or Cr.

A thickness of dielectric material layer 22 in the direction perpendicular to main surface 9 is smaller than thicknesses of electrically insulating layers 38 and 39 in the same direction. The thickness of dielectric material layer 22 in the direction perpendicular to main surface 9 is, for example, 0.01 μm to 0.5 μm. The thickness of electrically insulating layer 38 in the same direction is, for example, 0.2 μm to 10 μm. The thickness of electrically insulating layer 39 in the same direction is, for example, 0.1 μm to 10 μm. In addition, the dielectric constant of dielectric material layer 22 is larger than the dielectric constants of electrically insulating layers 38 and 39. The dielectric constant of dielectric material layer 22 is, for example, 20 p(pico) F/m to 500 p(pico) F/m. The dielectric constant of electrically insulating layer 38 is, for example, 10 p(pico) F/m to 200 p(pico) F/m. The dielectric constant of electrically insulating layer 39 is, for example, 10 p(pico) F/m to 200 p(pico) F/m.

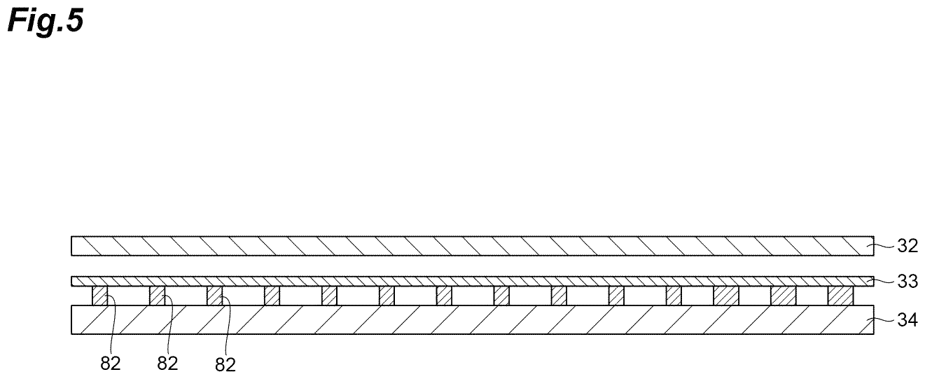

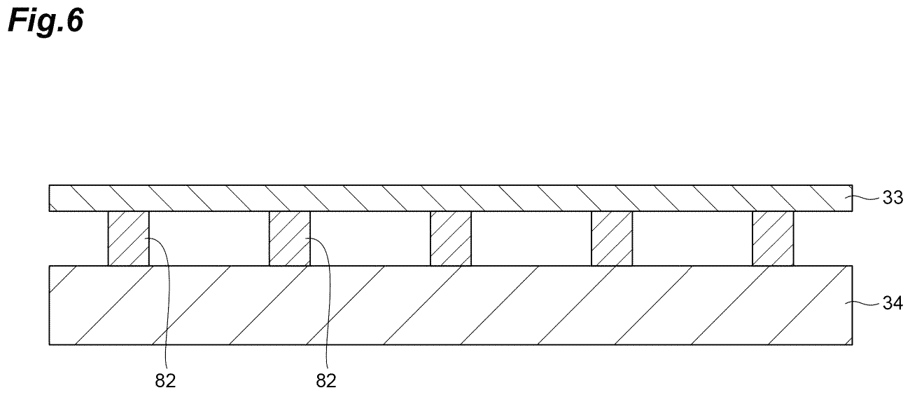

FIG. 5 is a cross-sectional view taken along line V-V shown in FIG. 1. FIG. 6 is a cross-sectional view taken along line VI-VI shown in FIG. 1. Amplifier 1 includes a plurality of vias 82 and a wiring 34 in addition to wiring 32 and wiring 33 described above. Wiring 34, the plurality of vias 82, wiring 33, and wiring 32 are provided between output terminal 72 and both of transistor 10 and MIM capacitors 20. Wiring 34 is formed integrally with wiring 16 in the same wiring layer as wiring 16, and extends from wiring 16 toward the outside of transistor 10. Wiring 33 is provided above wiring 34. Wiring 33 is formed integrally with lower electrode 21 in the same wiring layer as lower electrode 21, and extends from lower electrode 21 toward the outside of transistor 10. One end of wiring 33 is connected to lower electrode 21. The other ends of wirings 33 and 34 are connected to one end of inductor 40 (see FIG. 1) of bias circuit 2. Wiring 33 functions as a transmission line of direct current. The plurality of vias 82 are interposed between wiring 34 and wiring 33, and are distributed over the entire region of wiring 34 and wiring 33. The plurality of vias 82 are provided to penetrate electrically insulating layer 38 (see FIG. 3) to connect wiring 34 and wiring 33 to each other. Wiring 32 is provided above wiring 33. Wiring 32 is formed integrally with upper electrode 23 in the same wiring layer as upper electrode 23, and extends from upper electrode 23 toward the outside of transistor 10. Referring to FIG. 1, one end of wiring 32 is connected to upper electrode 23 of each MIM capacitor 20. The other end of wiring 32 is connected to output terminal 72 via an inductor 90 (not shown in FIG. 1). Wiring 32 functions as a transmission line of a signal (RF signal) amplified in transistor 10.

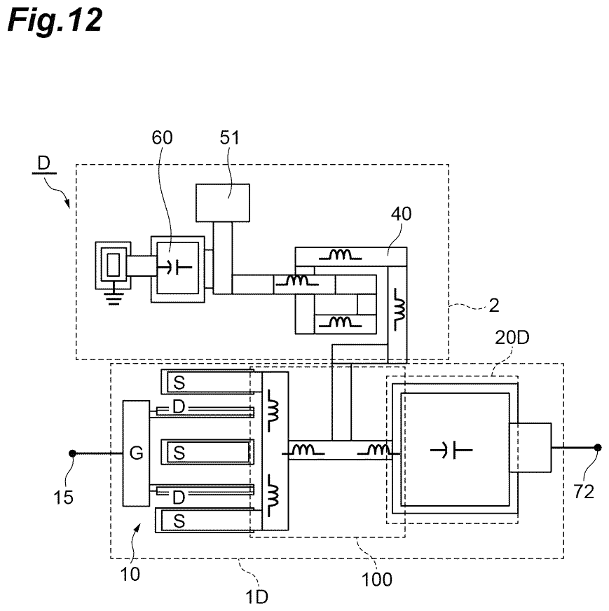

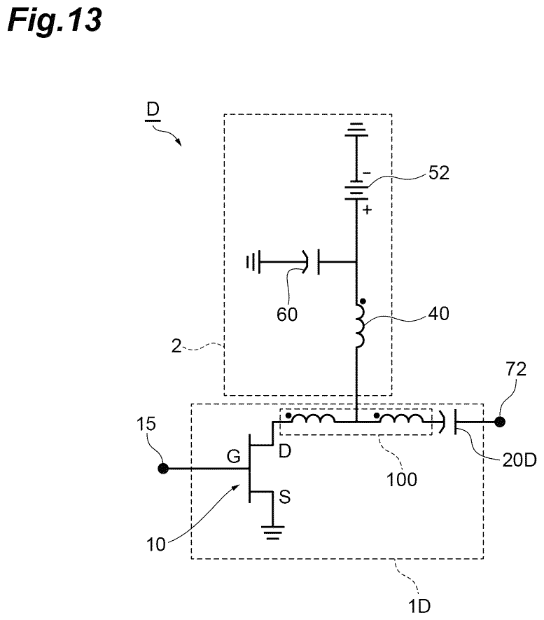

The effects obtained from semiconductor device A including the above configuration will be described. FIG. 12 is a plan view showing a semiconductor device D that is a comparative example. FIG. 13 is a circuit diagram of semiconductor device D that is a comparative example. Semiconductor device D is different from semiconductor device A in the following points. Semiconductor device D includes an amplifier 1D instead of amplifier 1. Amplifier 1D includes a MIM capacitor 20D instead of MIM capacitor 20. MIM capacitor 20D is not provided above transistor 10, but is provided outside transistor 10. Amplifier 1D has a routing wiring part 100 for connecting transistor 10 and MIM capacitor 20D. In semiconductor device D, since routing wiring part 100 becomes longer, an inductance component (indicated by inductor symbol in FIG. 12) in semiconductor device D becomes larger. Due to the influence of the inductance component, the adjustment of impedance becomes complicated, and the wiring length tends to be long. As the wiring length becomes longer, the loss increases and the efficiency of amplifier ID is likely to decrease.

In contrast, in semiconductor device A, MIM capacitor 20 is formed above transistor 10, and drain electrode 11 of transistor 10 and lower electrode 21 of MIM capacitor 20 are electrically connected to each other by the plurality of vias 81. Thus, the distance between transistor 10 and MIM capacitor 20 is shorter than the distance between transistor 10 and MIM capacitor 20D in the case where drain electrode 11 and lower electrode 21 are connected by routing wiring part 100. Thus, the magnitude of the inductance component between transistor 10 and MIM capacitor 20 in the configuration of semiconductor device A is smaller than that in the case where transistor 10 and MIM capacitor 20D are connected by routing wiring part 100. Thus, since the loss is reduced, semiconductor device A in which the efficiency of the amplifier is less likely to be reduced can be realized.

In addition, the surface of ohmic electrode 35 is roughened by annealing during the manufacturing process, and thus the surface of wiring 16 is also roughened. However, in the film formation process of electrically insulating layer 38 provided between wiring 16 and lower electrode 21, the surface of electrically insulating layer 38 is less likely to inherit the condition of the surface of wiring 16. That is, even when the surface of wiring 16 has irregularities, the surface of electrically insulating layer 38 can be made nearly flat. Thus, the surface of lower electrode 21 formed on electrically insulating layer 38 can also be made flat. Thus, it is possible to reduce electric field from locally increasing, and the reliability of MIM capacitor 20 can be enhanced.

Further, since the plurality of vias 81 are interposed between drain electrode 11 and lower electrode 21, the sum of the cross-sectional areas of all the plurality of vias 81 in the plane along main surface 9 is increased as compared with the case where a single via is provided, and thus current flows more easily between wiring 16 and lower electrode 21. Thus, the loss is reduced, thereby reducing the efficiency of amplifier 1 from being reduced.

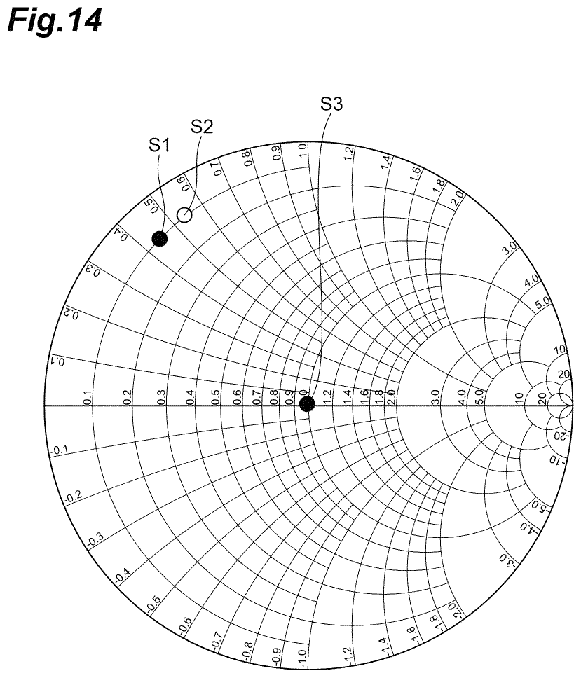

FIG. 14 is a Smith chart showing impedance characteristics of semiconductor device A according to the first embodiment and semiconductor device D according to the comparative example. In FIG. 14, a design value S1, a relay value S2, and a target value S3 are shown. In semiconductor device D, the impedance follows a traveling route from design value S1 to target value S3 via relay value S2 due to the influence of the inductance component by routing wiring part 100. Thus, the traveling route of the impedance tends to be long. In contrast, in semiconductor device A, since the plurality of vias 81 are provided instead of routing wiring part 100, the impedance follows a traveling route directly reaching target value S3 from design value S1. Thus, the traveling route of the impedance is shortened, and thus the wiring length can be shortened. Since the wiring length is short, the loss is reduced. Thus, according to the present embodiment, it is possible to realize semiconductor device A in which the efficiency of amplifier 1 is less likely to decrease.

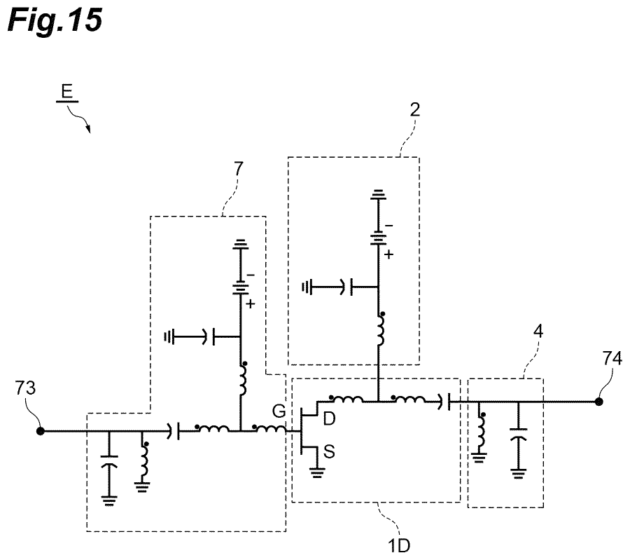

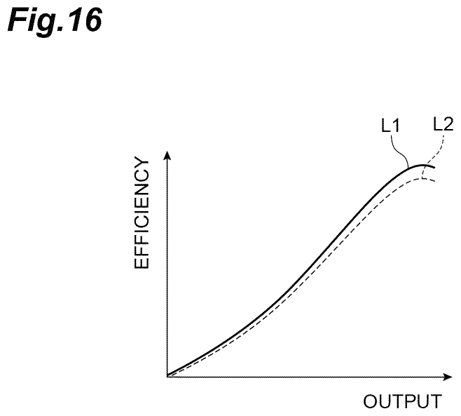

FIG. 15 is a circuit diagram of an amplifier circuit E that is a verification example. Amplifier circuit E includes an input terminal 73, an output terminal 74, a filter circuit 4, bias circuit 2, amplifier 1D of the comparative example, and a gate bias circuit 7. FIG. 16 is a diagram showing the characteristics (the relationship between the output and the efficiency) of amplifier circuit E that is the verification example. In FIG. 16, a graph line L1 and a graph line L2 are shown. Graph line L2 shows the characteristics of amplifier circuit E shown in FIG. 15. Graph line L1 shows the characteristic of amplifier circuit E in the case where amplifier 1 of the present embodiment is provided instead of amplifier 1D. In graph line L1 of FIG. 16, since the plurality of vias 81 are provided instead of routing wiring part 100, the inductance component is reduced, and the loss is reduced. Thus, the efficiency of the amplifier circuit is improved.

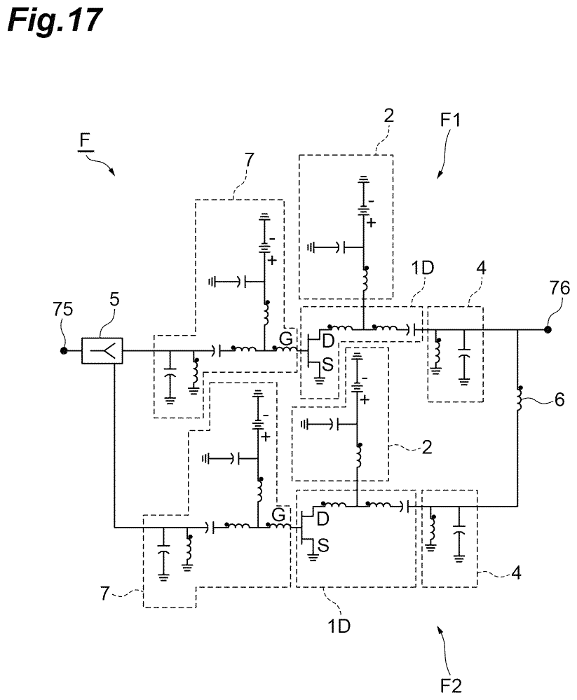

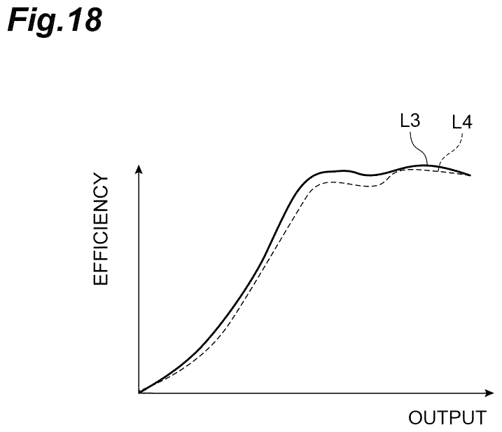

FIG. 17 is a circuit diagram of a Doherty amplifier circuit F that is a verification example. Doherty amplifier circuit F includes an input terminal 75, an output terminal 76, a divider 5, a wiring 6, and two amplifier circuits F1 and F2. Each of amplifier circuits F1 and F2 includes filter circuit 4, bias circuit 2, amplifier ID of the comparative example, and gate bias circuit 7. FIG. 18 is a diagram showing characteristics (the relationship between the output and the efficiency) of Doherty amplifier circuit F that is the verification example. In FIG. 18, a graph line L3 and a graph line L4 are shown. Graph line L4 shows the characteristics of Doherty amplifier circuit F shown in FIG. 17. Graph line L3 shows the characteristics of Doherty amplifier circuit F in the case where amplifier 1 of the present embodiment is provided instead of amplifier 1D. In graph line L3 of FIG. 18, since the plurality of vias 81 are provided instead of routing wiring part 100, the inductance component is reduced, and the loss is reduced. Thus, the efficiency of the Doherty amplifier circuit is improved.

As in the present embodiment, MIM capacitor 20 may be provided to avoid an area above gate electrode 13 of transistor 10. Thus, parasitic capacitance generated between MIM capacitor 20 and gate electrode 13 can be reduced. Thus, the parasitic capacitance is reduced in addition to the reduction of the inductance component, thereby further reducing the efficiency of amplifier 1 from being reduced.

As in the present embodiment, MIM capacitor 20 may fit in an area above drain electrode 11 of transistor 10 when viewed in the direction perpendicular to main surface 9. Thus, the portion where MIM capacitor 20 is formed is limited to an area above drain electrode 11, thereby reducing the parasitic capacitance generated between MIM capacitor 20 and the region other than drain electrode 11. Thus, the parasitic capacitance is reduced in addition to the reduction of the inductance component, thereby further reducing the efficiency of amplifier 1 from being reduced.

As in the present embodiment, transistor 10 may be a HEMT including a III-V group semiconductor. Generally, HEMT can withstand a high voltage and can handle a large current, and thus, can amplify a high output. Thus, the efficiency of amplifier I can be further improved by using the HEMT as transistor 10.

As in the present embodiment, the dielectric constant of dielectric material layer 22 may be larger than the dielectric constants of electrically insulating layers 38 and 39. This makes it possible to further increase the capacitance of MIM capacitor 20. Thus, the cut-off frequency decreases. Thus, it is possible to perform DC cutting at a lower frequency, and it is possible to perform DC cutting in a wide frequency bandwidth.

As in the present embodiment, the thickness of dielectric material layer 22 in the direction perpendicular to main surface 9 may be smaller than the thicknesses of electrically insulating layers 38 and 39 in the same direction. By reducing the thickness of dielectric material layer 22, the capacitance of MIM capacitor 20 can be increased. Thus, the cut-off frequency decreases. Thus, it is possible to perform DC cutting at a lower frequency, and it is possible to perform DC cutting in a wide frequency bandwidth.

As in the present embodiment, the thickness of lower electrode 21 in the direction perpendicular to main surface 9 may be smaller than the thickness of wiring 16 in the same direction. By reducing the thickness of lower electrode 21, deposition time of electrically insulating layer 39 that embeds lower electrode 21 can be shortened.

As in the present embodiment, the length of via 81 in the direction perpendicular to main surface 9 may be 0.1 μm to 10 μm. As in the comparative example described above, when routing wiring part 100 is provided between transistor 10 and MIM capacitor 20D, the distance between transistor 10 and MIM capacitor 20D tends to be long distance of, for example, several hundred micrometer or more. In contrast, according to semiconductor device A, the distance of the wiring (via 81) between transistor 10 and MIM capacitor 20 can be shortened in this manner. Thus, a semiconductor device in which the efficiency of amplifier 1 is less likely to be reduced can be realized.

### Second Embodiment

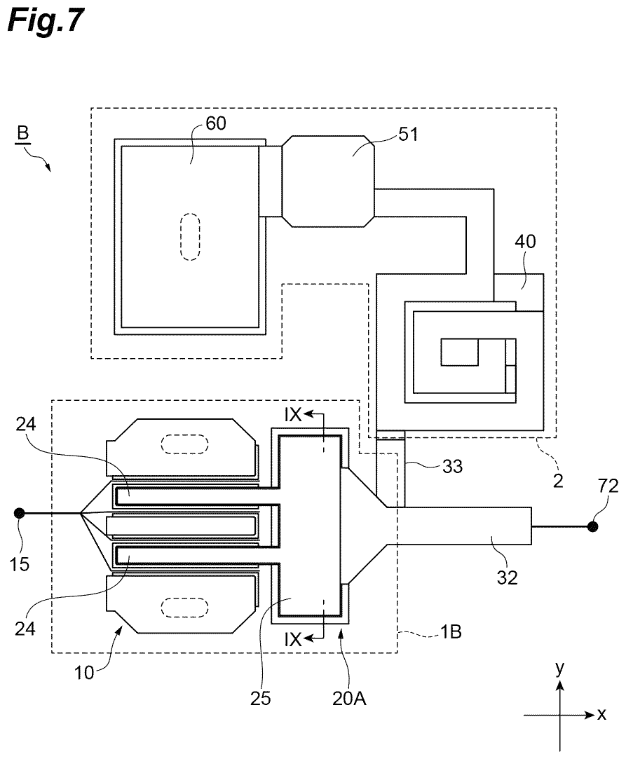

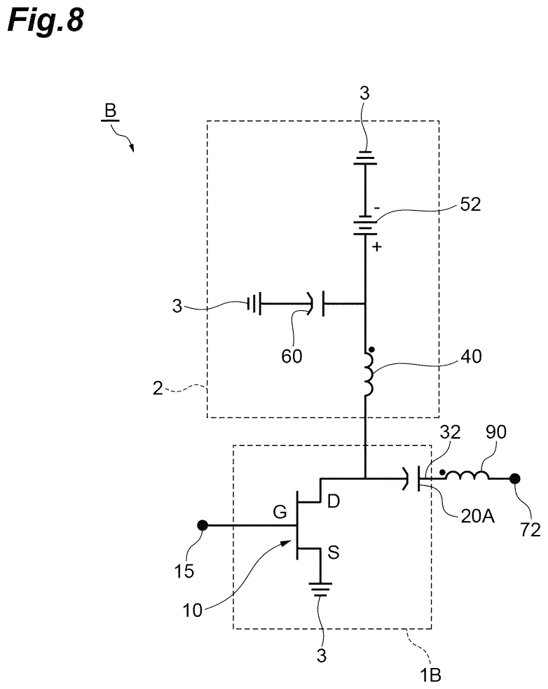

FIG. 7 is a plan view showing a semiconductor device B according to the second embodiment. FIG. 8 is a circuit diagram of semiconductor device B according to the second embodiment. Semiconductor device B is different from semiconductor device A in the following points, and is the same as semiconductor device A in other points. Semiconductor device B includes an amplifier 1B instead of amplifier 1. Amplifier 1B includes a MIM capacitor 20A instead of MIM capacitor 20. The other configuration of amplifier 1B is the same as that of amplifier 1. MIM capacitor 20A includes two first portions 24 and a second portion 25. Each first portion 24 fits in an area above drain electrode 11 when viewed in the direction perpendicular to main surface 9. Each first portion 24 has the same configuration as MIM capacitor 20 of the above embodiment. Second portion 25 is continuous with first portion 24 and is provided outside transistor 10 (specifically, between transistor 10 and wiring 32) when viewed in the direction perpendicular to main surface 9.

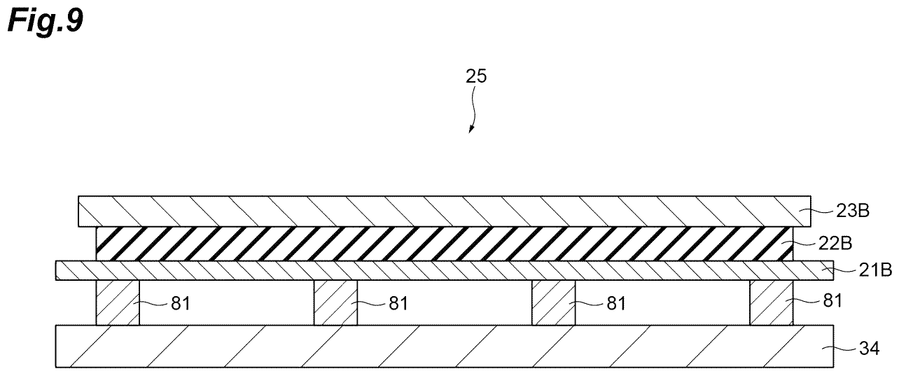

FIG. 9 is a cross-sectional view taken along line IX-IX shown in FIG. 7. As shown in FIG. 9, second portion 25 includes a lower electrode 21B, a dielectric material layer 22B provided on lower electrode 21B, and an upper electrode 23B provided on dielectric material layer 22B. Lower electrode 21B of second portion 25 is formed integrally with lower electrode 21 of first portion 24 in the same wiring layer. Lower electrode 21B is connected to wiring 34 via the plurality of vias 81. Dielectric material layer 22B of second portion 25 is the dielectric material layer common to dielectric material layer 22 of first portion 24. Upper electrode 23B of second portion 25 is formed integrally with upper electrode 23 of first portion 24 in the same wiring layer. Second portion 25 has a rectangular shape elongated along a direction (y direction) intersecting with the extending direction (x direction) of first portion 24 when viewed in the direction perpendicular to main surface 9.

In the present embodiment, one end of wiring 32 is connected to upper electrode 23B. The other end of wiring 32 is connected to output terminal 72. Wiring 32 functions as a transmission line of a signal (RF signal) amplified in transistor 10.

The effects obtained from semiconductor device B including the above configuration will be described. In semiconductor device B, parasitic capacitance generated between MIM capacitor 20A and a region other than drain electrode 11 can be reduced in both first portion 24 and second portion 25. In addition, since MIM capacitor 20A has second portion 25 in addition to first portion 24, the area of the electrode of MIM capacitor 20A can be increased, and thus the capacitance of MIM capacitor 20A can be increased. Thus, the cut-off frequency decreases. Thus, it is possible to perform DC cutting at a lower frequency, and it is possible to perform DC cutting in a wide frequency bandwidth.

### Third Embodiment

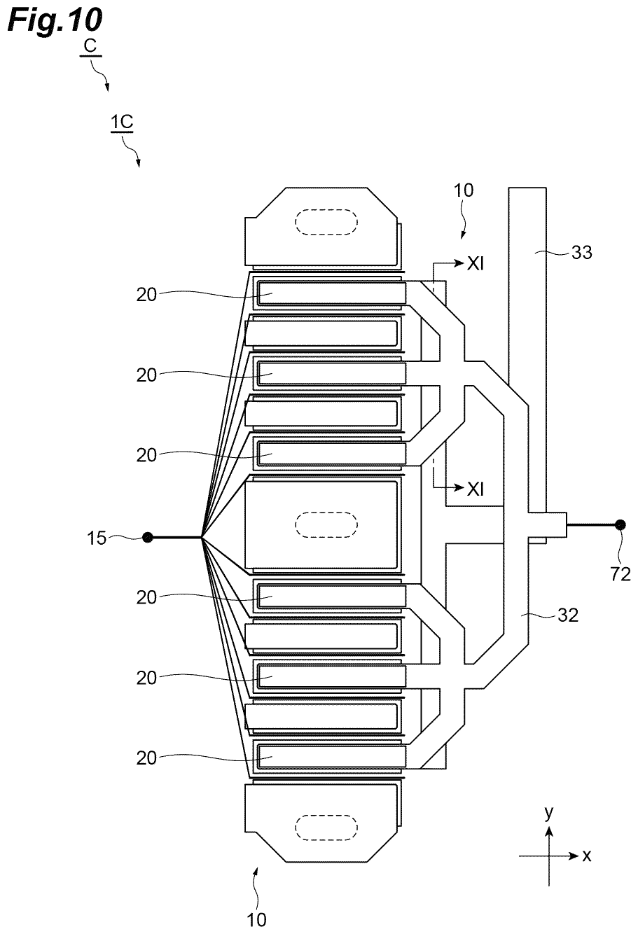

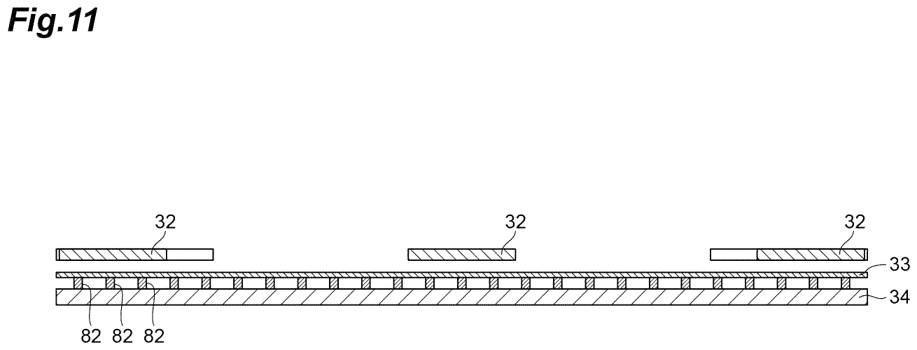

FIG. 10 is a plan view showing an amplifier 1C of a semiconductor device C according to the third embodiment. Amplifier 1C includes transistor 10 and the plurality of MIM capacitors 20. Transistor 10 of amplifier 1C includes six drain electrodes 11, seven source electrodes 12, and twelve gate electrodes 13. Drain electrodes 11 and source electrodes 12 are alternately arranged in the y direction, and gate electrodes 13 are arranged between drain electrodes 11 and source electrodes 12. Each MIM capacitor 20 is provided above each drain electrode 11. FIG. 11 is a cross-sectional view taken along line XI-XI shown in FIG. 10. In the present embodiment, the configurations of wiring 32, wiring 33, and wiring 34 are similar to those in the first embodiment.

Semiconductor device C having the above configuration also achieves similar effect as semiconductor device A. Further, the area of the entire electrodes of MIM capacitors 20 in semiconductor device C is larger than that in semiconductor device A. Thus, the capacitance of MIM capacitor 20 can be increased. Thus, the cut-off frequency decreases. Thus, it is possible to perform DC cutting at a lower frequency, and it is possible to perform DC cutting in a wide frequency bandwidth.

The semiconductor device according to the present disclosure is not limited to the above-described embodiments, and various modifications are possible. For example, although MIM capacitor 20 is provided above drain electrode 11 in the first embodiment, MIM capacitor 20 may be provided above source electrode 12 depending on the configuration of a circuit in which the semiconductor device is used. In each of the above embodiments, the two or six MIM capacitors 20 are provided above transistor 10, but the number of MIM capacitors 20 is not limited to this.

What is claimed is:

1. A semiconductor device comprising:
a transistor provided on a main surface of a substrate having the main surface, and including a first electrode including an ohmic electrode;
a MIM capacitor formed above the transistor and including a second electrode, a first electrically insulating layer provided on the second electrode, and a third electrode provided on the first electrically insulating layer;
a second electrically insulating layer provided between the first electrode and the second electrode; and
a plurality of vias penetrating the second electrically insulating layer and electrically connecting the first electrode and the second electrode to each other.

2. The semiconductor device according to claim 1, wherein the MIM capacitor is provided to avoid an area above a gate electrode of the transistor.

3. The semiconductor device according to claim 1, wherein the MIM capacitor fits in an area above the first electrode when viewed in a direction perpendicular to the main surface.

4. The semiconductor device according to claim 1,
wherein the MIM capacitor includes
a first portion fitting in an area above the first electrode when viewed in a direction perpendicular to the main surface, and
a second portion provided outside the transistor when viewed in the direction perpendicular to the main surface, the second portion being continuous with the first portion.

5. The semiconductor device according to claim 1, wherein the transistor is a HEMT including a III-V group semiconductor.

6. The semiconductor device according to claim 1, wherein a dielectric constant of the first electrically insulating layer is larger than a dielectric constant of the second electrically insulating layer.

7. The semiconductor device according to claim 1, wherein a thickness of the first electrically insulating layer in a direction perpendicular to the main surface is smaller than a thickness of the second electrically insulating layer in the direction perpendicular to the main surface.

8. The semiconductor device according to claim 1, wherein a thickness of the second electrode in a direction perpendicular to the main surface is smaller than a thickness of the first electrode in the direction perpendicular to the main surface.

9. The semiconductor device according to claim 1, wherein lengths of the plurality of vias in a direction perpendicular to the main surface is 0.1 μm to 10 μm.
